(19) United States
(12) Patent Application Publication
(10) Pub. No.: US 2025/0140667 A1
(43) Pub. Date: May 1, 2025

(54) SEMICONDUCTOR PACKAGE AND METHOD

(71) Applicant: Taiwan Semiconductor Manufacturing Co., Ltd., Hsinchu (TW)

(72) Inventors: Chih-Chiang Chang, New Taipei City (TW); Hua-Wei Tseng, New Taipei City (TW); Ta-Hsuan Lin, Hsinchu (TW); Wei-Cheng Wu, Hsinchu (TW); Der-Chyang Yeh, Hsinchu (TW)

(21) Appl. No.: 18/590,271

(22) Filed: Feb. 28, 2024

Related U.S. Application Data
(60) Provisional application No. 63/592,973, filed on Oct. 25, 2023.

(51) Int. Cl. H01L 23/498; H01L 23/00; H01L 23/31; H01L 23/367; H01L 23/522; H01L 25/00; H01L 25/065; H01L 25/18

(52) U.S. Cl. CPC H01L 23/49822; H01L 23/3121; H01L 23/3675; H01L 23/49816; H01L 23/5226; H01L 24/16; H01L 24/32; H01L 24/73; H01L 24/94; H01L 25/0655; H01L 25/18; H01L 25/50; H01L 2224/16225; H01L 2224/32225; H01L 2224/73204; H01L 2224/94; H01L 2924/1431; H01L 2924/1436; H01L 2924/1437

(57) ABSTRACT

In a semiconductor package having a redistribution structure, two or more semiconductor dies are connected to a first side of the redistribution structure and an encapsulant surrounds the two or more semiconductor dies. An integrated passive device (IPD) is connected on a second side of the redistribution structure. The second side is opposite to the first side and the IPD is electrically coupled to the redistribution structure. An interconnect device is connected on the second side of the redistribution structure and is electrically coupled to the redistribution structure. Two or more external connections are on the second side of the redistribution structure and are electrically coupled to the redistribution structure.

### PRIORITY CLAIM AND CROSS-REFERENCE

This application claims the benefit of U.S. Provisional Application No. 63/592,973, filed on Oct. 25, 2023, entitled “InFO Chip-let Structure to Integrate IPD and LSI Last with C4 Bump Technology,” which is incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from repeated reduction of minimum feature size, which allows more components to be integrated into a given area. As the demand for shrinking electronic devices has grown, a need for smaller and more creative packaging techniques of semiconductor dies has emerged. As chiplet technology continues to advance and the need for chiplet bridging to improve functionality and performance grows, die-to-die (D2D) interconnection for power delivery and signal transmission are implemented. It would be desirable to increase the number of D2D interconnects to increase the power delivery and signal transmission interconnections to accommodate the increase in integration density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die, in accordance with some embodiments.

FIGS. 2, 3, 4, 5, 6, 7, 8, 9A, 9B, 10A, 10B, and 10C illustrate various cross-sectional views, side views, and a top view of intermediate stages for producing a semiconductor package that includes semiconductor devices, local silicon interconnect (LSI) devices, and integrated passive devices (IPDs), in accordance with some embodiments of the disclosure.

FIGS. 11, 12A, 12B, 12C, 12D, 13, 14A, 14B, 14C, and 14D illustrate cross-sectional views of intermediate stages of producing a semiconductor package having external connections, in accordance with some embodiments of the disclosure.

FIG. 15 illustrates cross-sectional view of connectors between semiconductor devices and LSI devices or IPDs, in accordance with some embodiments of the disclosure.

FIG. 16 illustrates a flow diagram of a process for generating a packaged semiconductor device, according to some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, in a semiconductor package, two or more integrated circuit dies, e.g., systems on a chip (SoCs), are connected to each other via a redistribution structure and one or more LSI devices. The two or more SoCs are also mounted on a package substrate, e.g., the substrate of the package, via external connections, e.g., controlled collapse chip connection (C4) bumps, that are connected between the redistribution structure and the package substrate to provide D2D interconnections with increased I/O counts between the SoCs and the package substrate. One or more integrated passive devices (IPDs) are additionally connected to the redistribution structure, between the external connections. Connecting the one or more IPDs to the redistribution structure, reduces the interconnection distance between the SoCs and the IPDs and increases the integrity of power and signals delivered to the IPDs.

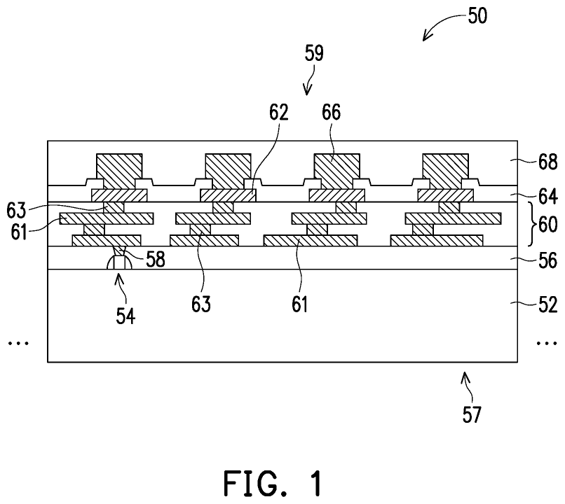

FIG. 1 illustrates a cross-sectional view of an integrated circuit die 50, e.g., a semiconductor die, in accordance with some embodiments. The integrated circuit die 50 will be packaged in the following to describe forming a semiconductor package. The integrated circuit die 50 may be, e.g., may include, a logic die (e.g., a central processing unit (CPU), a graphics processing unit (GPU), a system-on-a-chip (SoC), and application processor (AP), a microcontroller, etc.). The integrated circuit die 50 may be a memory die (e.g., a dynamic random access memory (DRAM) die, a static random access memory (SRAM) die, etc.). The integrated circuit die 50 may be one of a power management die (e.g., a power management integrated circuit (PMIC) die), a radio frequency (RF) die, a sensor die, a micro-electro-mechanical-system (MEMS) die, a signal processing die (e.g., digital signal processing (DSP) die), a front-end die (e.g., an analog front-end (AFE) die), and the like, or a combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. In some embodiments, the integrated circuit die 50 includes a semiconductor substrate 52, such as a silicon substrate, doped or undoped. The semiconductor substrate 52 may include an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the semiconductor substrate 52 has an active surface (e.g., the surface facing upwards in FIG. 1), which may be called a front side, and has an inactive surface (e.g., the surface facing downwards in FIG. 1), which may be called a back side.

One or more devices 54, e.g., one device shown in FIG. 1, may be formed at the front surface of the semiconductor substrate 52. The devices 54 may be active devices (e.g., transistors, diodes, etc.), or passive devices (e.g. capacitors, resistors, etc.) An inter-layer dielectric (ILD) 56 is formed over the front surface of the semiconductor substrate 52. The ILD 56 may surround and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 may extend through the ILD 56 to electrically and physically couple the devices 54. In some embodiments, when the devices 54 are transistors, the conductive plugs 58 may couple to the gates and/or to the source/drain regions of the transistors. Source/drain region(s) may refer to a source or a drain region, individually or collectively dependent upon the context. The conductive plugs 58 may be formed of tungsten, cobalt, nickel, copper, silver, gold, aluminum, the like, or combinations thereof. In some embodiments, an interconnect layer 60 is formed over the ILD 56 and conductive plugs 58. The interconnect layer 60 may include an interconnect structure be coupled to the conductive plugs 58 of the devices 54 to interconnect the devices 54 to form an integrated circuit. The interconnect structure of the interconnect layer 60 may be formed by, for example, metallization patterns in dielectric layers on the ILD 56. The metallization patterns include metal lines and vias formed in one or more low-k dielectric layers. As described, the metallization patterns of the interconnect layer 60 are electrically coupled to the devices 54 via the conductive plugs 58. The interconnect structure in the interconnect layer 60 may include conductive layers 61 that are connected to each other through vias 63. In some embodiments, the interconnect structure of the interconnect layer 60 is an RDL structure.

The integrated circuit die 50 further includes pads 62, such as aluminum pads, to which external connections are made. The pads 62 are on the active side of the integrated circuit die 50, such as in and/or on the interconnect layer 60 and in contact with the interconnect structure. One or more passivation films 64 are on the integrated circuit die 50, such as on portions of the interconnect layer 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be formed on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect layer 60 or the interconnect structure. As shown, a side of the semiconductor substrate 52 of the integrated circuit die 50 away from the ILD 56 is a backside 57 of the integrated circuit die 50 and a side 59 of the integrated circuit die 50, opposite of the backside 57 is a front side of the integrated circuit die 50.

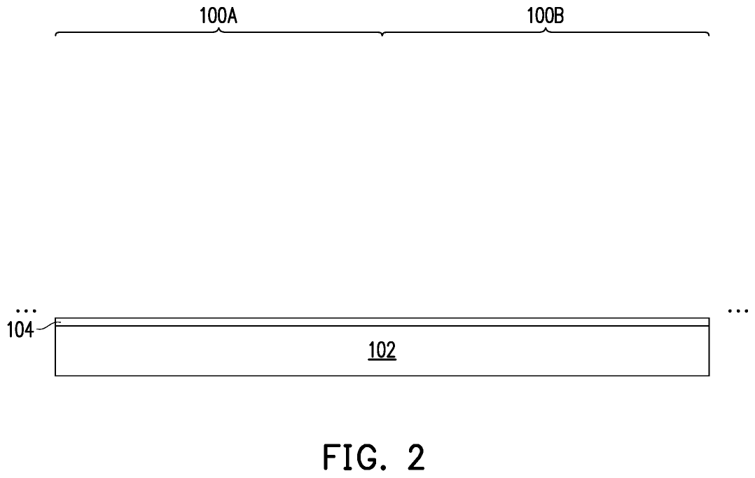

FIGS. 2, 3, 4, 5, 6, 7, 8, 9A, 9B, 10A, 10B, and 10C illustrate various cross-sectional views, side views, and a top view of intermediate stages for producing a semiconductor package that includes semiconductor devices, LSI devices (e.g., interconnect devices), and integrated passive devices (IPDs), in accordance with some embodiments of the disclosure. A first package region 100A and a second package region 100B are illustrated, and one or more of the integrated circuit dies 50 are packaged to form an integrated circuit package in each of the package regions 100A and 100B. The integrated circuit packages may also be referred to as integrated fan-out (InFO) packages.

In FIG. 2, a carrier substrate 102 is provided, and a release layer 104, e.g., a die attach file (DAF), is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

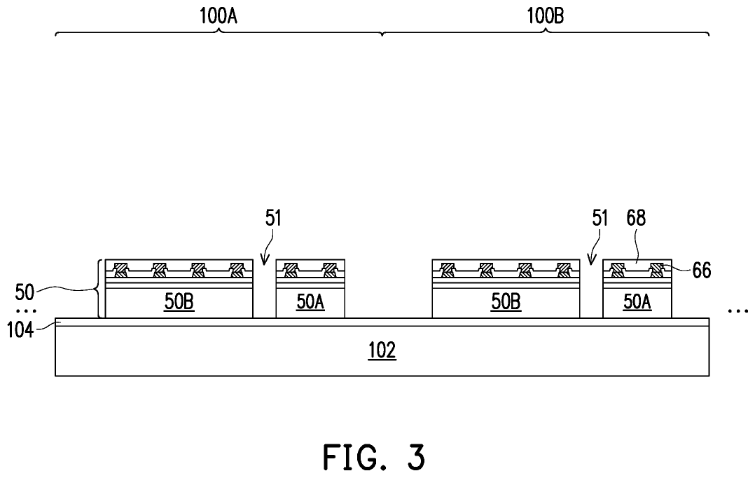

In FIG. 3, integrated circuit dies 50 (e.g., a first integrated circuit die 50A and a second integrated circuit die 50B) are connected to the release layer 104. A desired type and quantity of integrated circuit dies 50 are adhered in each of the package regions 100A and 100B. In the embodiment shown, multiple integrated circuit dies 50 are adhered adjacent one another, including the first integrated circuit die 50A and the second integrated circuit die 50B in each of the first package region 100A and the second package region 100B. The first integrated circuit die 50A may be a logic device, such as a CPU, a GPU, a SoC, an AP, a microcontroller, or the like. The second integrated circuit die 50B may be a memory device, such as a DRAM die, an SRAM die, a hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). As shown, the integrated circuit die 50A has a larger surface area compared to the integrated circuit die 50B.

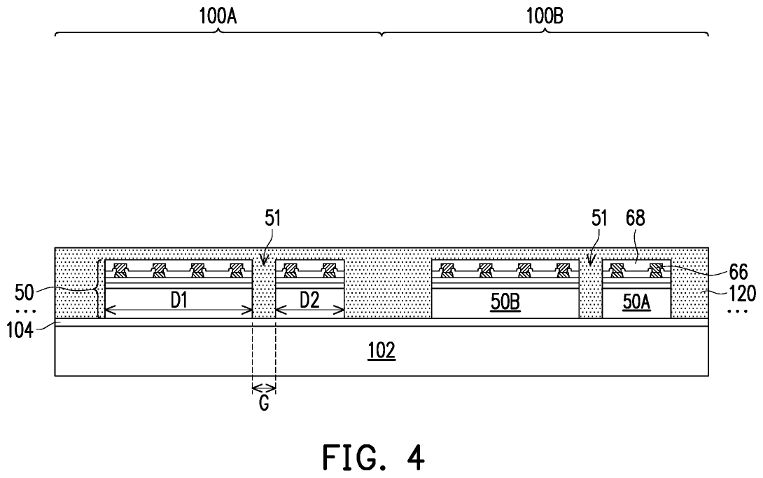

In FIG. 4, an encapsulant 120, e.g., an encapsulant material, is formed on and around the integrated circuit dies 50. After formation, the encapsulant 120 encapsulates the integrated circuit dies 50. The encapsulant 120 may be a molding compound, epoxy, or the like. The encapsulant 120 may be applied by compression molding, transfer molding, or the like, and may be formed over the carrier substrate 102 such that the integrated circuit dies 50 are buried or covered. The encapsulant 120 is further formed in gap regions 51 between the integrated circuit dies 50. The encapsulant 120 may be applied in liquid or semi-liquid form and then subsequently cured. In some embodiments, the integrated circuit dies 50 in each package region 100A or 100B are next to each other, e.g., at proximity of each other, such that an extent G of the gap between integrated circuit dies 50 in each package region is not more than a maximum extent of the two or more semiconductor dies, e.g., maximum of D1 and D2. In some embodiments, the encapsulant 120 extends from the backside 57 to the front side 59 of the integrated circuit dies 50 and surround a height of the integrated circuit dies 50 and may cover the front side 59 of the integrated circuit dies 50.

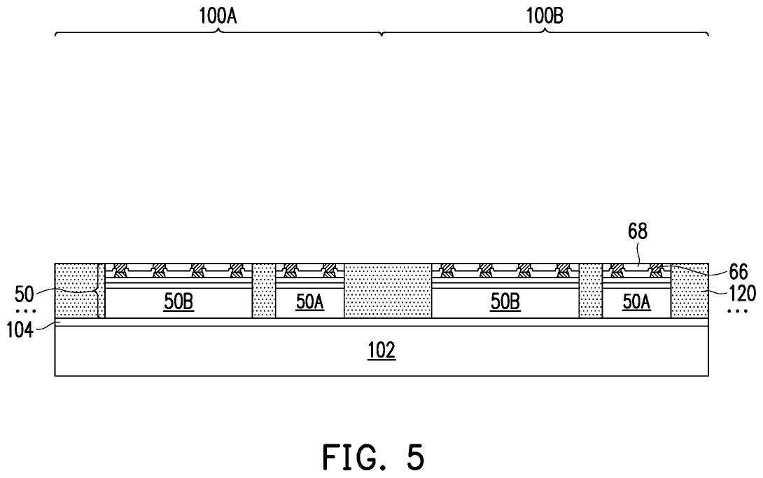

In FIG. 5, a planarization process is performed on the encapsulant 120 to expose the die connectors 66, e.g., connection pads of the integrated circuit dies 50. The planarization process may also remove material of the dielectric layer 68 and/or the die connectors 66 until the die connectors 66 are exposed, e.g., a top surface of the die connectors 66 are exposed. Top surfaces of the die connectors 66, the dielectric layer 68, and the encapsulant 120 are substantially coplanar after the planarization process within process variations. The planarization process may be, for example, a chemical-mechanical polish (CMP), a grinding process, or the like. In some embodiments, the planarization may be omitted, for example, if the die connectors 66 are already exposed.

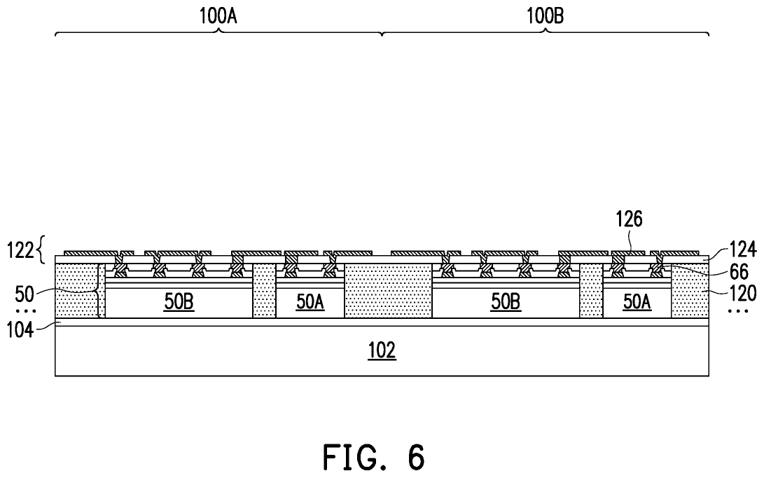

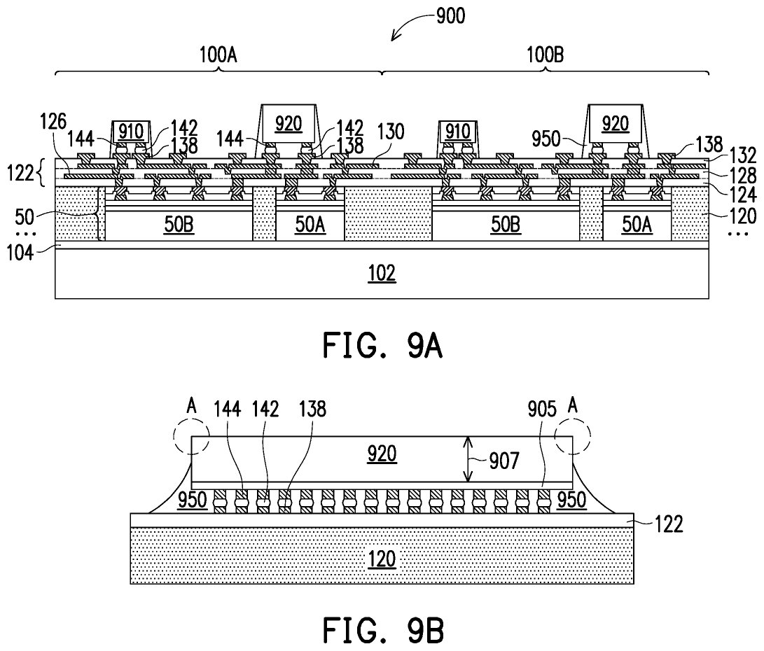

In FIGS. 6 through 8, a redistribution structure 122, e.g., a front-side redistribution structure (see FIG. 9A) is formed over the encapsulant 120 and integrated circuit dies 50. The redistribution structure 122 includes dielectric layers 124, 128, and 132; and metallization patterns 126 and 130. The metallization patterns may also be referred to as redistribution layers or redistribution lines. The redistribution structure 122 is shown as an example having three layers of metallization patterns. More or fewer dielectric layers and metallization patterns may be formed in the redistribution structure 122. If fewer dielectric layers and metallization patterns are to be formed, steps and process discussed below may be omitted. If more dielectric layers and metallization patterns are to be formed, steps and processes discussed below may be repeated.

In FIG. 6, the dielectric layer 124 is deposited on the encapsulant 120 and die connectors 66. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the die connectors 66. The patterning may be by an acceptable process, such as by exposing and developing the dielectric layer 124 to light when the dielectric layer 124 is a photo-sensitive material or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically couple to the integrated circuit dies 50, e.g., couple to the die connectors 66. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

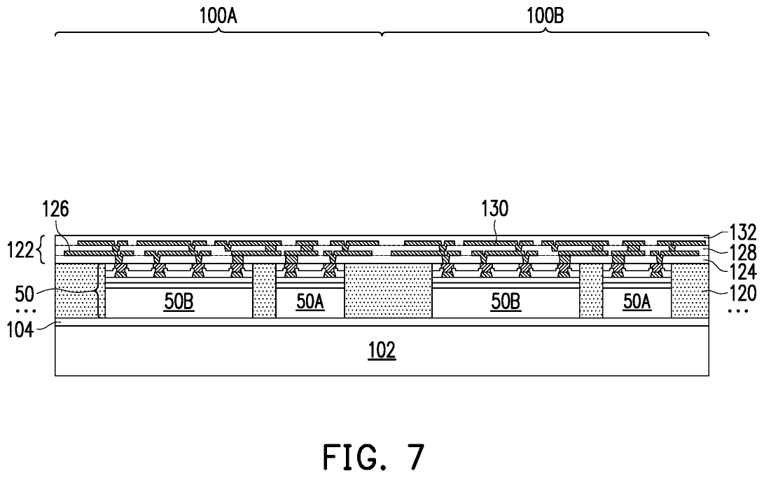

In FIG. 7, the dielectric layer 128 is deposited on the metallization pattern 126 and the dielectric layer 124. The dielectric layer 128 may be formed in a manner similar to the dielectric layer 124, and may be formed of a similar material as the dielectric layer 124.

The metallization pattern 130 is then formed. The metallization pattern 130 includes portions on and extending along the major surface of the dielectric layer 128. The metallization pattern 130 further includes portions extending through the dielectric layer 128 to physically and electrically couple to the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126.

Additionally, as shown in FIG. 7, the dielectric layer 132 is deposited on the metallization pattern 130 and the dielectric layer 128. The dielectric layer 132 may be formed in a manner similar to the dielectric layer 124, and may be formed of a similar material as the dielectric layer 124. The metallization pattern 130 is the topmost metallization pattern of the redistribution structure 122. As such, all of the intermediate metallization patterns of the redistribution structure 122 (e.g., the metallization pattern 126) are disposed between the metallization pattern 130 and the integrated circuit dies 50.

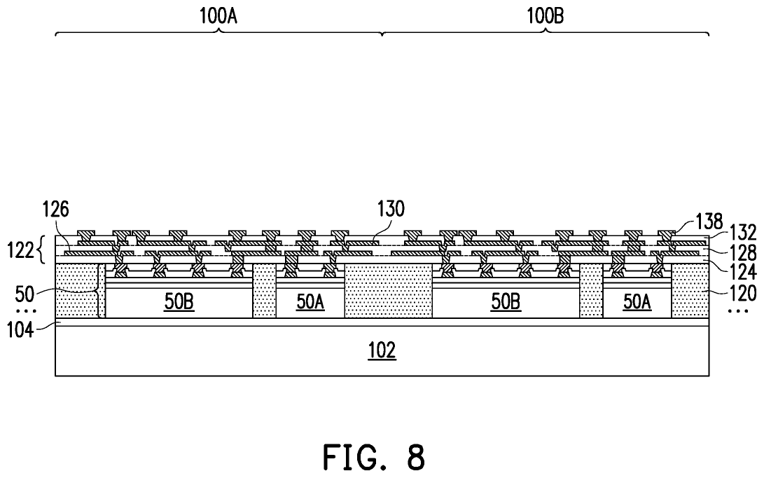

In FIG. 8, under-bump metallizations (UBMs) 138, which are conductive features, are formed on and connected to the metallization pattern 130 for external connection to the redistribution structure 122. The UBMs 138 have bump portions on and extending along the major surface of the dielectric layer 132, and have via portions extending through the dielectric layer 132 to physically and electrically couple to the metallization pattern 130. As a result, the UBMs 138 are electrically coupled to the integrated circuit dies 50. The UBMs 138 may be formed of the same material as the metallization pattern 126. In some embodiments, the UBMs 138 have a different size than the metallization patterns 126 and 130.

FIG. 9A shows the semiconductor structure 900 that includes the package regions 100A and 100B and is attached to the carrier substrate 102 via the release layer 104. In FIG. 9A, an IPD 910 and an LSI device 920 are connected via the UBMs 138 to the redistribution structure 122 in the package regions 100A and 100B. In some embodiment, as shown, the LSI device 920 is connected, via the redistribution structure 122, to the integrated circuit dies 50A and 50B. Also, the LSI device 920 may overlap with both the IPD 910 and the LSI device 920 or may overlap with one of the IPD 910 or the LSI device 920. Also, the IPD 910 may be connected, via the redistribution structure 122 to one or both of the integrated circuit dies 50 (e.g., the integrated circuit dies 50A and/or 50B). The connection to the UBMs 138 is through a contact pad 144 of the IPD 910 or the LSI device 920 and through micro bumps 142. In some embodiments, a height of the IPD 910 is smaller than a height of the LSI device 920 or vice versa and in some embodiments, the IPD 910 and the LSI device 920 have substantially the same height. As shown, the IPD 910 and the LSI device 920 may be coupled via the redistribution structure 122 to the integrated circuit dies 50 of each package region 100A or 100B. In some embodiments, each package region 100A or 100B includes one or more LSI device 920 and one or more IPDs 910. As shown, a space between the LSI devices 920 and the redistribution structure 122 and also the space between the IPD 910 and the dielectric layer 132 of the redistribution structure 122 are filled with an underfill material 950. In some embodiments, the area size of the LSI device 920 is between 6 and 20 mm² and the package region (e.g., the package region 100A and the package region 100B) may include multiple LSI devices, such as about 4 LSI devices 920.

FIG. 9B shows a side view of the LSI device 920 before being thinned, e.g., being grinded. In some embodiments, a height 907 of the LSI device 920, before being thinned, is between 700 microns and 800 microns, e.g., 775 microns. Also, the LSI device 920 may include one or more metallization layers, collectively referred to as a metallization layer 905, that is connected to the contact pads 144 described above and the metallization layer 905 may connect the LSI device 920 to the redistribution structure 122. As shown in locations A, on both sides of the LSI device 920, top of the LSI device 920 is above the top of the underfill material 950. As discussed, the LSI device 920 may overlap the integrated circuit dies 50A and 50B and may be in electrical contact with the integrated circuit dies 50A and 50B that are covered by the encapsulant 120. In some embodiments, a height of the IPD 910 before being grinded is between 60 microns and 70 microns, e.g., 64 microns, and the height of the IPD 910 after being grinded, is between 30 microns and 50 microns, e.g., 35 microns.

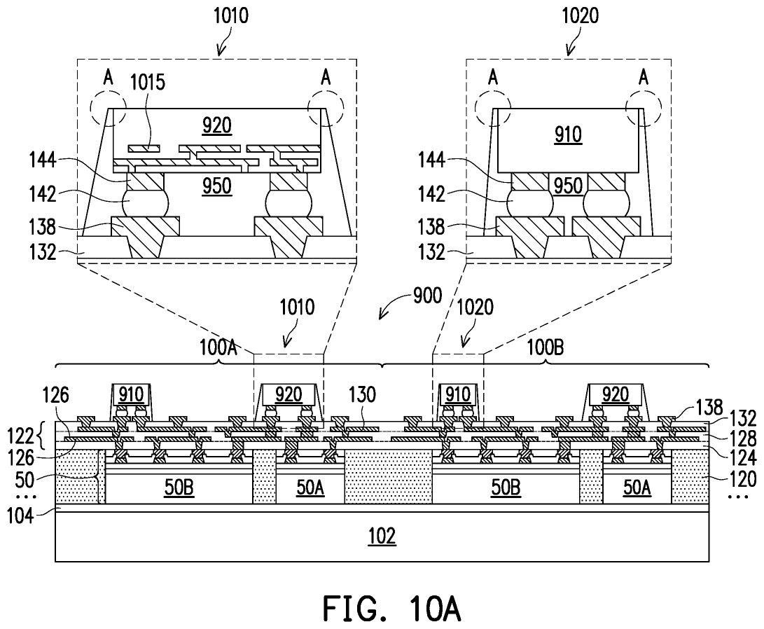

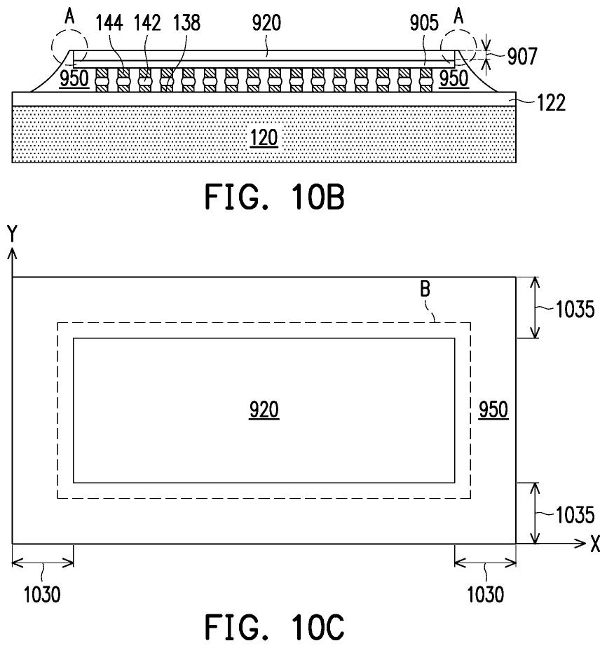

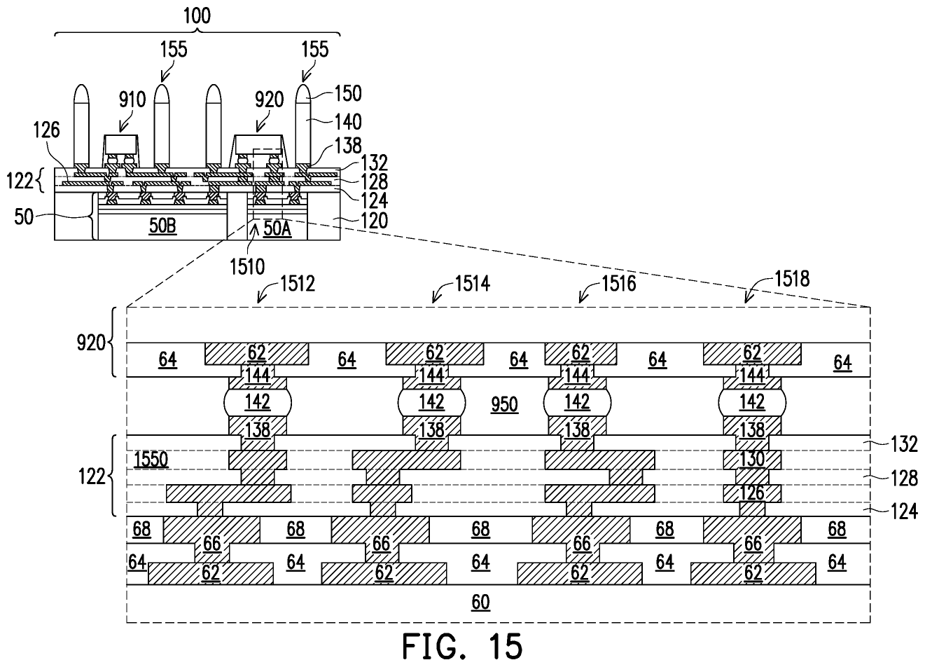

In FIG. 10A, the IPDs 910 and the LSI devices 920 are thinned using, for example, a grinding process on a backside of the IPDs 910 and the LSI devices 920, to make a height of the IPDs 910 and a height of the LSI devices 920 substantially the same within process variations. FIG. 10A also shows a magnified image of a region 1010 having the LSI devices 920 and anther magnified image of a region 1020 having the IPD 910. As shown, the underfill material 950 may extend by an amount between 5 microns and 20 microns beyond the width and/or length of the LSI devices 920 or the IPD 910 as shown in locations A. In some embodiments, only the underfill material 950 under the LSI devices 920 extends beyond the width of the LSI devices 920. As shown, the LSI device 920 may include one or more layers of electrical routing 1015. The details of the electrical connection between the LSI device 920 and the integrated circuit dies 50 is described with respect to FIG. 15. As shown, the IPD 910 and the LSI device 920 are at least partially facing or overlapping one or more of the integrated circuit dies 50 and are electrically coupled to one or more of integrated circuit dies 50. Because the IPD 910 and/or the LSI device 920 are connected to a first side of the redistribution structure 122 and the integrated circuit dies 50 are connected to a second side, opposite to the first side, of the redistribution structure 122, the overlapping may be described as facing each other. Thus, when the IPD 910 and/or the LSI device 920 and the integrated circuit dies 50 are facing or overlapping each other, a perpendicular projection of the IPD 910 and/or the LSI device 920 from the first side onto the second side, at least partially overlaps an area covered by the integrated circuit dies 50 on the second side of the redistribution structure 122. In some embodiments, the area size of the IPD 910 is between 2 and 6 mm² and the package region (e.g., the package region 100A and the package region 100B) may include multiple IPDs 910, such as about 10 IPDs 910.

FIG. 10B shows a side view of the LSI device 920 after being thinned. In some embodiments, the height 907 of the LSI device 920, after being thinned, is between 30 microns and 50 microns, e.g., 40 microns. As shown in locations A, on both sides of the LSI device 920, the top of the LSI device 920 is substantially level with the top of the underfill material 950, within process variations. FIG. 10C shows a top view of the LSI device 920. In some embodiments, the underfill material 950 extends beyond the LSI device 920 by a distance 1030 in the X direction and extends beyond the LSI device 920 by a distance 1035 in the Y direction that is perpendicular to the X direction. In some embodiments, the distance 1030 and the distance 1035 are between 5 microns and 20 microns. In some embodiments, in an extended region B around the LSI device 920, the underfill material 950 has substantially the same height as the LSI device 920, within process variations. In some embodiments, the extended region B extends between 1 micron to 5 microns beyond edges of the LSI device 920 in both X and Y directions.

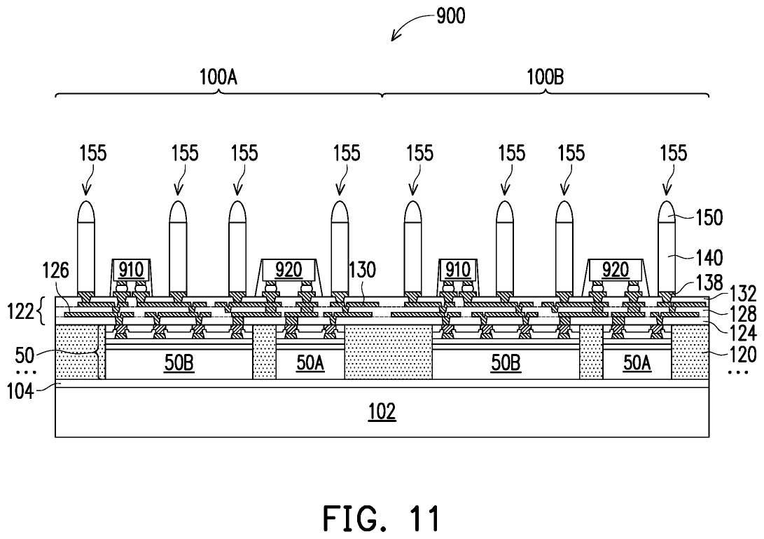

FIGS. 11, 12A, 12B, 12C, 12D, 13, 14A, 14B, 14C, and 14D illustrate cross-sectional views of intermediate stages of producing a semiconductor package having external connections, in accordance with some embodiments of the disclosure.

FIG. 11 shows external connections 155, such as the C4 bumps, that are connected to the UBMs 138. Each of the external connections 155 may include a conductive pillar 140, e.g., a metal pillar, and a solder connection 150 connected to the conductive pillar 140. In some embodiments, the conductive pillar 140 includes copper and the solder connection 150 may include tin, silver, or copper. In some embodiments, the height of the solder connection 150 of the external connections 155 is greater than the height of the LSI devices 920 or the height of the IPD 910 and the external connections 155 are electrically coupled to the redistribution structure 122 via the UBMs 138. In some embodiments, a distance between external connections 155, e.g., external connection pitch, is between 80 microns and 130 microns, e.g., 90 microns.

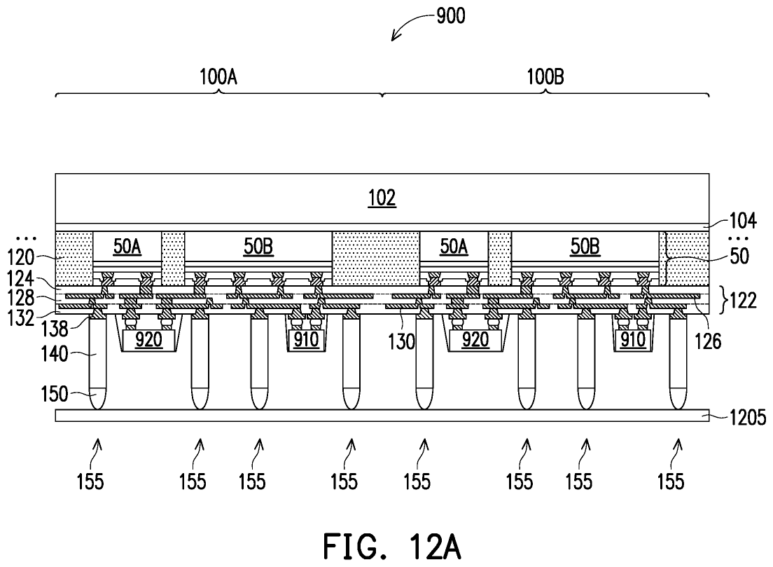

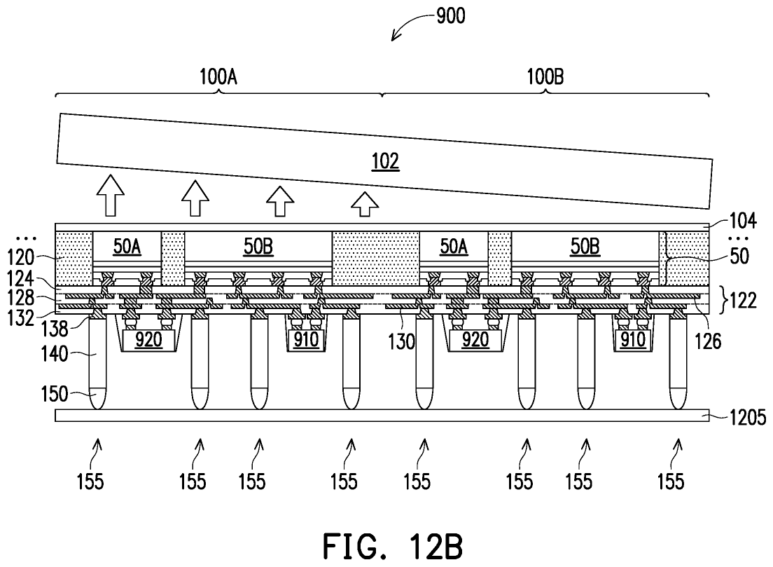

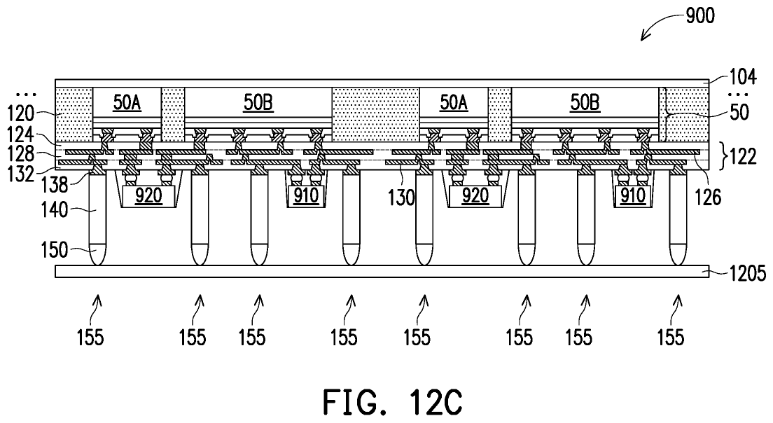

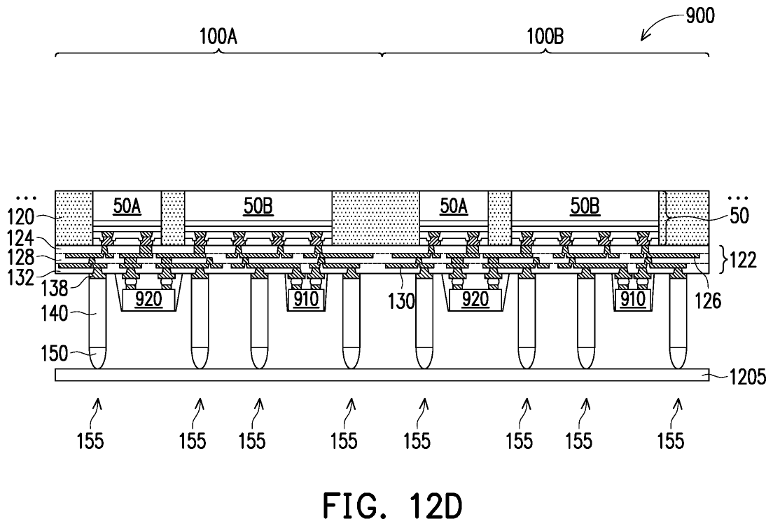

In FIG. 12A, as shown, the semiconductor structure 900 is flipped over and is attached to an adhesive layer 1205, e.g., an adhesive tape. The adhesive layer 1205 may be used to provide support in the next procedure as shown in FIG. 12B. In FIG. 12B, a carrier substrate de-bonding is performed to detach (or “de-bond”) the carrier substrate 102 from the semiconductor substrates 52 and the encapsulant 120. In accordance with some embodiments, the de-bonding includes projecting a light such as a laser light or a UV light on the release layer 104 so that the release layer 104 is decomposed under the heat of the light and the carrier substrate 102 can be removed. As shown in FIG. 12A, the adhesive layer 1205 may be attached over the semiconductor structure 900 and on the external connections 155. Then the semiconductor structure 900 may be flipped over and the carrier substrate 102 may be removed from the release layer 104 as shown in FIG. 12B. As shown in FIG. 12C, after the removal of the carrier substrate 102, the release layer 104 may remain on the back of the integrated circuit dies 50A and 50B and on the encapsulant 120. Then, as shown in FIG. 12D, the release layer 104 may be removed.

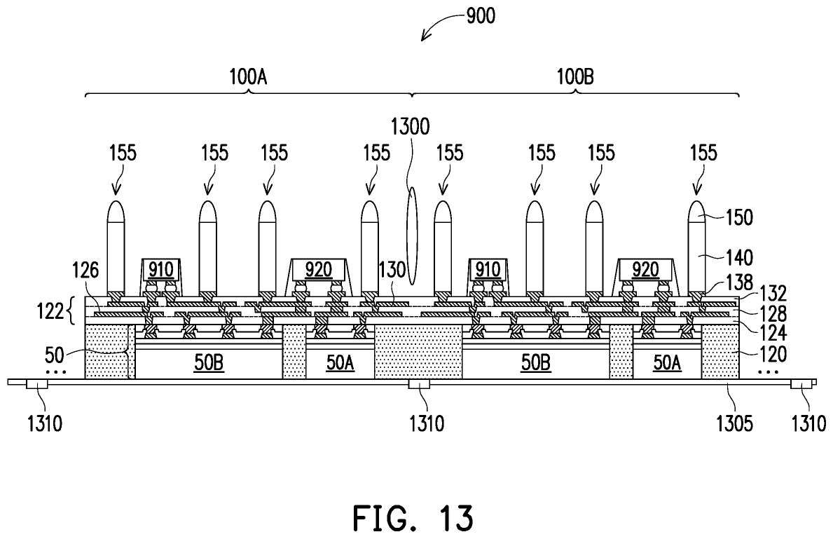

As shown in FIG. 13, the adhesive layer 1205 may be removed, the semiconductor structure 900 is then flipped again and placed on an adhesive layer or tape (an adhesive tape 1305 of FIG. 13 consistent with the adhesive layer 1205). In some embodiments,

In FIG. 13, a substrate, e.g., the semiconductor structure 900, that is placed on the adhesive tape 1305 and includes the package regions 100A and 100B is singulated by a blade 1300. In FIGS. 2 through 13, the substrate extends in two dimensions and includes a plurality of the package regions similar to the package regions 100A and 100B. As shown, the package regions are singulated by the blade 1300. As shown, before singulating, the adhesive tape 1305, e.g., a dicing tape, is attached to the back of the integrated circuit dies 50A and 50B and on the encapsulant 120. Further, die markers 1310 may be attached to the adhesive tape 1305. Then, the dies are singulated (cut) by the blade 1300 at the locations where die markers 1310 are show.

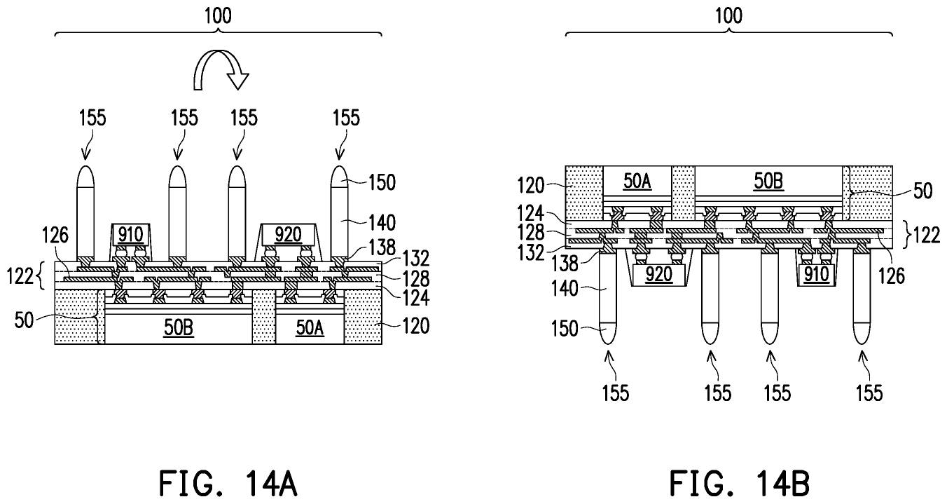

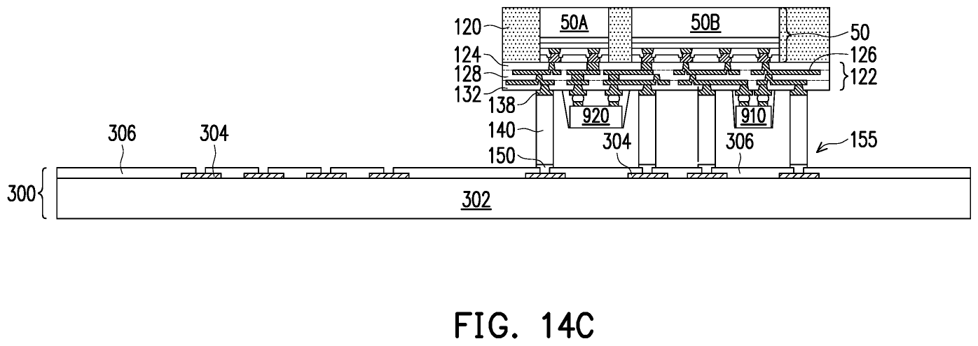

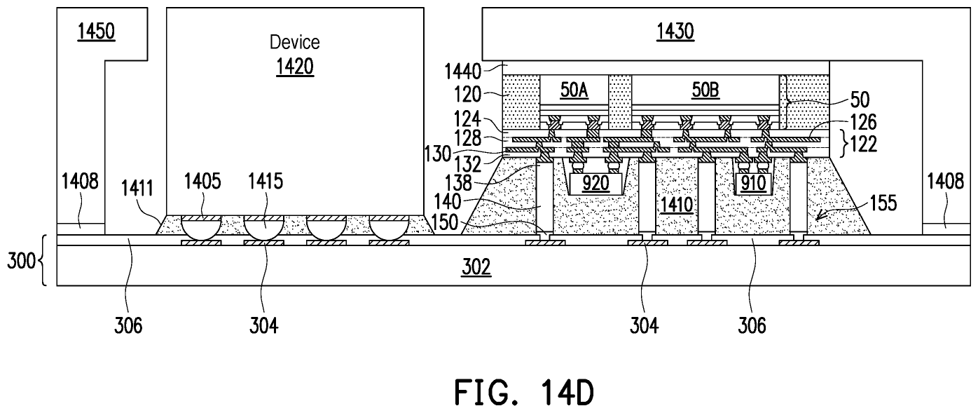

FIG. 14A shows a singulated package region 100 and FIG. 14B shows the singulated package region 100 of FIG. 14A that is flipped over. FIG. 14C shows the flipped over package region 100 that is mounted on a package substrate 300. The package substrate 300 includes a substrate core 302 and bond pads 304 over the substrate core 302. The substrate core 302 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 302 may be an SOI substrate. Generally, an SOI substrate includes a layer of a semiconductor material such as epitaxial silicon, germanium, silicon germanium, SOI, SGOI, or combinations thereof. The substrate core 302 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 302.

The package substrate 300 may include a passivation layer 306, e.g., a dielectric layer, that is formed on the substrate core 302. In some embodiments, the passivation layer 306 is etched such that the substrate core 302 is exposed and bond pads 304 are disposed on the etched portions of the passivation layer 306. Thus, the bond pads 304 may be electrically connected to the substrate core 302.

The substrate core 302 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 302 may also include metallization layers and vias (not shown), with the bond pads 304 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 302 is substantially free of active and passive devices. The semiconductor devices of the substrate core 302 may communicate to the integrated circuit dies 50 through the external connections 155, the LSI device 920, and redistribution structure 122.

FIG. 14D shows the flipped over package region 100 that is mounted on the package substrate 300 and underfill material 1410 that is disposed between the package substrate 300 and the redistribution structure 122, which surrounds the external connections 155, the LSI devices 920, and the IPDs 910. Additionally, another device in the form of a device die 1420 is mounted via solder bumps 1415 to the package substrate 300. The solder bumps 1415 that are surrounded by an underfill material 1411 are coupled between device die pads 1405 of the device die 1420 and the bond pads 304 of package substrate 300. The device die 1420 may communicated with the integrated circuit dies 50A and/or 50B through the package substrate 300. In some embodiments, the device die 1420 includes a memory structure, e.g., a dynamic random access memory (DRAM). As shown, FIG. 14D shows heat conductive lids 1430 and 1450 that are mounted on the package substrate 300 via adhesive layers 1408. The heat conductive lid 1430 is thermally connected to the back of the integrated circuit dies 50A and 50B via a heat conductive layer 1440 to remove the generated heat of the integrated circuit dies 50A and 50B. The heat conductive lids 1430 and 1450 may act as a heat sink or may be thermally connected to heat sinks (not shown) to dissipate the heat generated by the device die 1420 and the integrated circuit dies 50A and 50B. In some embodiments, the package area size is between 100 mm² and 600 mm² and an area covered by the integrated circuit dies 50A and 50B is between 80 mm² and 400 mm².

FIG. 15 illustrates cross-sectional view of connectors between semiconductor devices and LSI devices or IPDs, in accordance with some embodiments of the disclosure. FIG. 15 shows a section 1510 of the package region 100. FIG. 15 shows portions of the LSI devices 920, the redistribution structure 122, and the integrated circuit die 50A. A similar section may exist between the IPDs 910, the redistribution structure 122, and the integrated circuit die 50B. The redistribution structure 122 shows the dielectric layer 1550 that includes the dielectric layers 124, 128, and 132 that includes vias for connecting metallization patterns 126 and 130. FIG. 15 shows the top part of the integrated circuit die 50A with the redistribution structure 122 that is connected to the die connectors 66 of the integrated circuit die 50A. FIG. 15 also shows the UBMs 138 that is connected to the redistribution structure 122 and the LSI devices 920 (or IPDs 910) that includes the contact pad 144 that are connected to pads 62 in the passivation films 64 such that the pads 62 and the contact pads 144 are connected via micro bumps 142. As shown, the vias in the dielectric layer 1550 may be arranged as jogged structure 1512 and 1514, a U-turn structure 1516, or a stacked structure 1518. In some embodiments, the width of the UBM 138, the micro bump 142, or the contact pads 144 is between 5 microns and 16 microns, e.g., 12 microns. In some embodiments, the height of the vias is between 4 microns and 8 microns, e.g., 5 microns and the width of the vias is between 3 microns and 15 microns, e.g., 8 microns or between 2 microns and 8 microns, e.g., 5 microns. In some embodiments, a thickness of the metallization patterns 126 and 130 is between 2 microns and 8 microns, e.g., 4 microns.

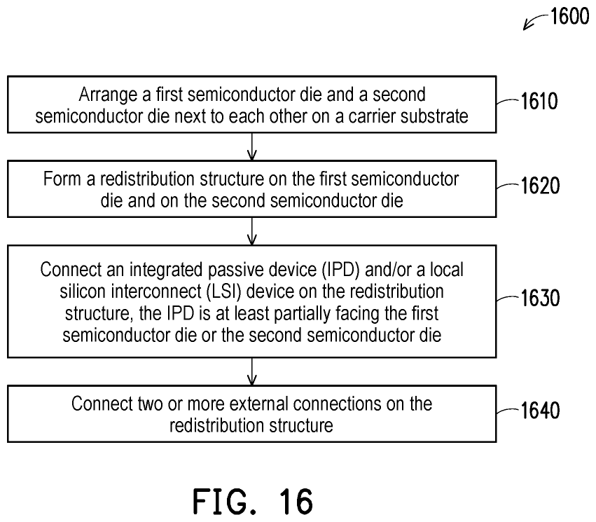

FIG. 16 illustrates a flow diagram of a process 1600 for generating a packaged semiconductor device, according to some embodiments of the disclosure. The steps of the process are shown in FIGS. 3, 4, 6, 7, 9, 10, and 11. At step 1610, a first semiconductor die and a second semiconductor die are arranged next to each other on a carrier substrate. As shown in FIG. 3, the first integrated circuit die 50A and the second integrated circuit die 50B are arranged on the carrier substrate 102. The integrated circuit dies 50A and 50B are next to each other such that as shown in FIG. 4, the distance G between them may be less than the maximum of the extent D1 of the integrated circuit die 50A and the extent D2 of the integrated circuit die 50B, or may be less than ten to twenty times the maximum of the extent D1 of the integrated circuit die 50A and the extent D2 of the integrated circuit die 50B.

At step 1620, a redistribution structure is formed that is connected and is electrically coupled to a front side of the first and on the second semiconductor dies. As shown in FIGS. 6 and 7, the redistribution structure 122 (a first side of the redistribution structure 122) is formed on the front side 59 of the first and second integrated circuit dies 50A and 50B. As shown, the redistribution structure 122 is connected and is electrically coupled to the first and second integrated circuit dies 50A and 50B via the die connectors 66.

At step 1630, an IPD and/or a LSI device (an interconnect device) is connected and is electrically coupled to the redistribution structure, opposite to a side connected to the first and the second semiconductor dies, the IPD and/or the LSI device is at least partially overlapping the first and/or the second semiconductor die, e.g., the IPD or the LSI device are connected at one side of the redistribution structure 122 and the first and the second integrated circuit dies 50A and 50B are connected at another opposite side of the redistribution structure 122 and the IPD or the LSI device is at least partially overlapping the first and the second integrated circuit dies 50A and 50B as described above. As shown in FIG. 9A, the IPD 910 and the LSI device 920 are connected and is electrically coupled to the redistribution structure 122 via UBMs 138.

At step 1640, two or more external connections are connected and are electrically coupled to the redistribution structure. As shown in FIG. 11, the external connections 155, e.g., the C4 bumps, are connected and are electrically coupled to the redistribution structure 122 via the UBMs 138. The external connections may provide D2D interconnections with increased I/O counts.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

As such, the packaged semiconductor system of FIG. 14D may be used in advanced networking and server applications (e.g., AI (Artificial Intelligence)) which operate with high data rates, high bandwidth demands and low latency. Furthermore, the of the packaged semiconductor system of FIG. 14D may be provided a high degree of chip package integration in a small form factor with high component and board level reliability.

In the embodiments described above integration of LSI bridging, IPD, and external connections, e.g., C4 bumps, on one side of the redistribution structure may be achieved. Only one layer of molding is used and, thus, warpage of the molding is not an issue. The D2D interconnection for power delivery and signal transmission with increased I/O counts between the SoCs and the package substrate. One or more IPDs are connected to the redistribution structure, between the external connections to reduce the interconnection distance between the SoCs and the IPDs and increases the stability of power delivery and integrity of signal delivery to the IPDs.

According to an embodiment, a semiconductor package includes a redistribution structure, two or more semiconductor dies connected to a first side of the redistribution structure, an encapsulant surrounding the two or more semiconductor dies, and an integrated passive device (IPD) connected on a second side of the redistribution structure. The second side is opposite to the first side and the IPD is electrically coupled to the redistribution structure. An interconnect device is connected on the second side of the redistribution structure and is electrically coupled to the redistribution structure. Two or more external connections are on the second side of the redistribution structure and are electrically coupled to the redistribution structure.

In an embodiment, a distance between two neighboring semiconductor dies is less than or equal to a maximum extent of the two or more semiconductor dies, and the IPD is at least partially overlapping a first semiconductor die of the two or more semiconductor dies and is at least electrically coupled to the first semiconductor die. In an embodiment, the interconnect device is at least partially overlapping a first semiconductor die and a second semiconductor die, and the interconnect device is electrically coupled to the first semiconductor die and the second semiconductor die. In an embodiment, each of the two or more semiconductor dies includes die connectors at a front side of the semiconductor die, and the first side of the redistribution structure is electrically coupled to the two or more semiconductor dies via the die connectors. The second side of the redistribution structure includes under-bump metallizations (UBMs). The interconnect device, the IPD, and the two or more external connections are electrically coupled to the redistribution structure via the UBMs. In an embodiment, the two or more external connections include a conductive pillar and a solder connection that is coupled to the conductive pillar. The IPD and the interconnect device have a height that is smaller than a height of solder connections of the external connections. In an embodiment, the semiconductor package further includes a package substrate connected to the external connections. The package substrate includes connection pads such that the solder connections of the external connections are connected to the connection pads. An underfill material is between the package substrate and the redistribution structure such that the underfill material surrounds the IPD, the interconnect device, and the external connections. In an embodiment, the semiconductor package further includes a heat conductive layer that is thermally coupled to a backside of the two or more semiconductor dies and a heat-dissipating lid that is thermally coupled to the heat conductive layer.

According to an embodiment, a semiconductor package includes a redistribution structure, a first semiconductor die and a second semiconductor die such that the first semiconductor die and the second semiconductor die are attached to a first side of the redistribution structure. The semiconductor package also includes an interconnect device that is connected on a second side of the redistribution structure. The interconnect device is electrically coupled to the first semiconductor die and the second semiconductor die. Two or more external connections are on the second side of the redistribution structure.

In an embodiment, the semiconductor package further includes an encapsulant surrounding the first semiconductor die and the second semiconductor die. In an embodiment, the semiconductor package further includes an integrated passive device (IPD) connected on the second side of the redistribution structure such that the IPD device is at least partially overlapping the first semiconductor die or the second semiconductor die and is electrically coupled to the first semiconductor die and the second semiconductor die. In an embodiment, a distance between the first semiconductor die and the second semiconductor die is less than or equal to a maximum extent of the first semiconductor die and the second semiconductor die, and the encapsulant surrounds the first and second semiconductor dies. In an embodiment, the external connections include a conductive pillar and a solder connection that is connected to the conductive pillar. The semiconductor package further includes a package substrate connected to the external connections such that the package substrate includes connection pads such that the solder connections of the external connections are connected to the connection pads. An underfill material is formed between the package substrate and the redistribution structure such that the IPD and the interconnect device have a height that is smaller than a height of the external connections, and the underfill material surrounds the IPD, the interconnect device, and the external connections. In an embodiment, the semiconductor package further includes a heat-dissipating lid mounted on the package substrate and thermally coupled to the first semiconductor die and the second semiconductor die. The semiconductor package further include a heat conductive layer that is thermally coupled between the heat-dissipating lid and backsides of the first semiconductor die and the second semiconductor die. In an embodiment, the redistribution structure includes vias having a U-turn structure.

According to an embodiment, a method semiconductor packaging includes arranging first and second semiconductor dies next to each other on a carrier substrate and forming a redistribution structure on the first semiconductor die and the second semiconductor die. A first side of the redistribution structure is overlapping the first semiconductor die and the second semiconductor die. The method also includes connecting an integrated passive device (IPD) on a second side of the redistribution structure such that the IPD is at least partially overlapping the first semiconductor die or the second semiconductor die. The method further includes connecting two or more external connections on the second side of the redistribution structure.

In an embodiment, the method further includes disposing an encapsulant on the carrier substrate such that the encapsulant is disposed around and between the first semiconductor die and the second semiconductor die. In an embodiment, the method further includes removing the carrier substrate from a backside of the first and second semiconductor dies. In an embodiment, the method further includes connecting connection pads of a package substrate to the external connections and forming an underfill material between the package substrate and the redistribution structure. A height of the IPD is smaller than a height of the two or more external connections, and the underfill material surrounds the IPD and the external connections. In an embodiment, the method further includes forming a heat conductive layer on a backside of the first and second semiconductor dies such that the heat conductive layer is thermally coupled to the backside of the first and second semiconductor dies, and mounting a heat-dissipating lid on the package substrate such that the heat-dissipating lid is thermally coupled to the heat conductive layer. In an embodiment, the method further includes mounting a memory device on the package substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a redistribution structure;
two or more semiconductor dies connected to a first side of the redistribution structure;
an encapsulant surrounding the two or more semiconductor dies;
an integrated passive device (IPD) connected on a second side of the redistribution structure, the second side being opposite to the first side, wherein the IPD is electrically coupled to the redistribution structure;
an interconnect device connected on the second side of the redistribution structure and electrically coupled to the redistribution structure; and
two or more external connections on the second side of the redistribution structure and electrically coupled to the redistribution structure.

2. The semiconductor package of claim 1, wherein a distance between two neighboring semiconductor dies is less than or equal to a maximum extent of the two or more semiconductor dies, and wherein the IPD is at least partially overlapping a first semiconductor die of the two or more semiconductor dies and is at least electrically coupled to the first semiconductor die.

3. The semiconductor package of claim 1, wherein the interconnect device is at least partially overlapping a first semiconductor die and a second semiconductor die, and wherein the interconnect device is electrically coupled to the first semiconductor die and the second semiconductor die.

4. The semiconductor package of claim 1, wherein:
each of the two or more semiconductor dies comprises die connectors at a front side of the two or more semiconductor dies, and wherein the first side of the redistribution structure is electrically coupled to the two or more semiconductor dies via the die connectors; and
the second side of the redistribution structure comprises under-bump metallizations (UBMs), and wherein the interconnect device, the IPD, and the two or more external connections are electrically coupled to the redistribution structure via the UBMs.

5. The semiconductor package of claim 1, wherein the two or more external connections comprise a conductive pillar and a solder connection that is coupled to the conductive pillar, and wherein the IPD and the interconnect device have a height that is smaller than a height of solder connections of the external connections.

6. The semiconductor package of claim 5, further comprising:
a package substrate connected to the external connections, where the package substrate comprises connection pads, and wherein the solder connections of the external connections are connected to the connection pads; and
an underfill material between the package substrate and the redistribution structure, wherein the underfill material surrounds the IPD, the interconnect device, and the external connections.

7. The semiconductor package of claim 1, further comprising:
a heat conductive layer thermally coupled to a backside of the two or more semiconductor dies; and
a heat-dissipating lid thermally coupled to the heat conductive layer.

8. A semiconductor package, comprising:
a redistribution structure;
a first semiconductor die and a second semiconductor die attached to a first side of the redistribution structure;
an interconnect device connected on a second side of the redistribution structure, wherein the interconnect device is electrically coupled to the first semiconductor die and the second semiconductor die; and
two or more external connections on the second side of the redistribution structure.

9. The semiconductor package of claim 8, further comprising:
an encapsulant surrounding the first semiconductor die and the second semiconductor die.

10. The semiconductor package of claim 9, further comprising:
an integrated passive device (IPD) connected on the second side of the redistribution structure, wherein the IPD device is at least partially overlapping the first semiconductor die or the second semiconductor die and is electrically coupled to the first semiconductor die and the second semiconductor die.

11. The semiconductor package of claim 10, wherein a distance between the first semiconductor die and the second semiconductor die is less than or equal to a maximum extent of the first semiconductor die and the second semiconductor die, wherein the encapsulant surrounds the first and second semiconductor dies.

12. The semiconductor package of claim 10, wherein the external connections comprise a conductive pillar and a solder connection connected to the conductive pillar, the semiconductor package further comprising:
a package substrate connected to the external connections, where the package substrate comprises connection pads, wherein the solder connections of the external connections are connected to the connection pads; and
an underfill material formed between the package substrate and the redistribution structure, wherein the IPD and the interconnect device have a height that is smaller than a height of the external connections, and wherein the underfill material surrounds the IPD, the interconnect device, and the external connections.

13. The semiconductor package of claim 12, further comprising:
a heat-dissipating lid mounted on the package substrate and thermally coupled to the first semiconductor die and the second semiconductor die, wherein a heat conductive layer is thermally coupled between the heat-dissipating lid and backsides of the first semiconductor die and the second semiconductor die.

14. The semiconductor package of claim 12, wherein:
the redistribution structure comprises vias having a U-turn structure.

15. A method, comprising:
arranging first and second semiconductor dies next to each other on a carrier substrate;
forming a redistribution structure on the first semiconductor die and the second semiconductor die, a first side of the redistribution structure overlapping the first semiconductor die and the second semiconductor die;
connecting an integrated passive device (IPD) on a second side of the redistribution structure, wherein the IPD is at least partially overlapping the first semiconductor die or the second semiconductor die; and
connecting two or more external connections on the second side of the redistribution structure.

16. The method of claim 15, further comprising:
disposing an encapsulant on the carrier substrate, wherein the encapsulant is disposed around and between the first semiconductor die and the second semiconductor die.

17. The method of claim 16, further comprising:
removing the carrier substrate from a backside of the first and second semiconductor dies.

18. The method of claim 16, further comprising:
connecting connection pads of a package substrate to the external connections; and
forming an underfill material between the package substrate and the redistribution structure, wherein a height of the IPD is smaller than a height of the two or more external connections, and wherein the underfill material surrounds the IPD and the external connections.

19. The method of claim 18, further comprising:
forming a heat conductive layer on a backside of the first and second semiconductor dies, wherein the heat conductive layer is thermally coupled to the backside of the first and second semiconductor dies; and
mounting a heat-dissipating lid on the package substrate, the heat-dissipating lid being thermally coupled to the heat conductive layer.

20. The method of claim 18, further comprising:
mounting a memory device on the package substrate.
